(19) United States
(12) Patent Application Publication
(10) Pub. No.: US 2014/0124651 A1
(43) Pub. Date: May 8, 2014

(54) COMPARATOR, COMPARISON METHOD, AD CONVERTER, SOLID-STATE IMAGE PICKUP DEVICE, AND ELECTRONIC APPARATUS

(71) Applicant: Sony Corporation, Tokyo (JP)

(72) Inventor: Tatsunori Nakahara, Fukuoka (JP)

(73) Assignee: SONY CORPORATION, Tokyo (JP)

(21) Appl. No.: 14/038,085

(22) Filed: Sep. 26, 2013

(30) Foreign Application Priority Data
Nov. 8, 2012 (JP) 2012-246536

(51) Int. Cl. H03K 3/013; G01J 1/44

(52) U.S. Cl. CPC H03K 3/013; G01J 1/44
USPC 250/208.1; 327/307; 341/164

(57) ABSTRACT

A comparator compares a pixel signal from a pixel with a reference signal an offset level of which is changed in a stepwise manner and performs auto zero to set the pixel signal at the offset level of the reference signal in accordance with one of a plurality of auto zero signals having different timings for instructing the auto zero.

### CROSS REFERENCE TO RELATED APPLICATIONS

This application claims the benefit of Japanese Priority Patent Application JP 2012-246536 filed Nov. 8, 2012, the entire contents of which are incorporated herein by reference.

### BACKGROUND

The present disclosure relates to a comparator, a comparison method, an AD converter, a solid-state image pickup device, and an electronic apparatus, in particular, to a comparator, comparison method, an AD converter, a solid-state image pickup device, and an electronic apparatus, which are used to suppress a generation of noise caused by a simultaneous inversion of comparator outputs.

A CMOS image sensor (hereinafter, which will be abbreviated as CIS) serving as a solid-state image pickup device used for a digital still camera or the like has been widely known.

FIG. 1 illustrates a configuration example of a CIS in related art. This CIS 10 is provided with an AD conversion unit (hereinafter referred to as ADC) configured to execute correlated double sampling (CDS) as digital signal processing to remove noise that may be generated in a pixel signal (for example, see Japanese Patent No. 4470700).

The CIS 10 includes a pixel array unit 11, a row scanning unit 12, a column scanning unit 13, a timing control unit 14, an AD converter (ADC) 15 provided for each column, a DAC 16, and a data output unit 17.

The pixel array unit 11 is composed of a large number of pixels 111 arranged in a matrix. The row scanning unit 12, the column scanning unit 13, and the timing control unit 14 are configured to sequentially read out signals of the pixel array unit 11. The row scanning unit 12 controls row addresses and row scannings. The column scanning unit 13 controls column addresses and column scannings. The timing control unit 14 generates an internal clock signal. The timing control unit 14 also generates an auto zero signal AZ0 which will be described below.

Each of the ADCs 15 is an integral ADC composed of a comparator (CMP) 151, an asynchronous up/down counter (CNT) 152, and a switch 153.

A common reference signal generated by the DAC 16 and an analog pixel signal corresponding to the amount of photo charge read out via a vertical signal line Vn (n=0, 1, . . . , n+1) from one of the pixels 111 are input to each of the comparators 151. The comparator 151 compares the reference signal and the pixel signal with each other and outputs signal of the comparison result to the asynchronous up/down counter (hereinafter, which will be abbreviated as counter) 152.

FIG. 2 illustrates an example of a circuit configuration of the comparators 151 arranged in a row direction. The common auto zero signal AZ0 supplied from the timing control unit 14 via the DAC 16 and a signal line, which are not illustrated in the drawing, is input to each of the comparators 151 as well as the above-mentioned common reference signal and the pixel signal. FIG. 3 illustrates an example of waveforms of the common auto zero signal, the common reference signal input to each of the comparator 151, and the common auto zero signal. The auto zero signal AZ0 is set at a low level in accordance with a timing at which the reference signal is set at VO level, that is, an offset level.

Each of the comparators 151 performs auto zero on the reference signal and the pixel signal while following the auto zero signal and inverts the signal of comparison result (the output of the comparator 151). With this auto zero, it is possible to set a comparison period of the counter 152 without an influence from a variation in the reset components of the respective pixels 111.

The counter 152 has a function of performing up/down count (or down count) on the basis of the comparison result of the comparator 151 and a clock CK to hold a count value corresponding to the result. The switch 153 connects the counter 152 and the data transfer line 18 with each other and performs opening and closing on the basis of the scanning control from the column scanning unit 13. The data output unit 17 including a sense circuit and a subtraction circuit corresponding to the data transfer line 18 is arranged on the data transfer line 18.

The counter 152 having the function as the holding circuit is set in an up count (or down count) state as an initial state and performs reset count. When the comparison result from the corresponding comparator 151 is inversed, the counter 152 stops the up count operation, and the count value is held. At this time, an initial value of the counter 152 is set as an arbitrary value of a gradation of the AD conversion, for example, 0. During this reset count period, the reset component of the respective pixels 111 is read out. After that, the counter 152 is set in a down count (or up count) state and performs data count corresponding to the incident light amount. When the comparison result of the corresponding comparator 151 is inversed, the count value in accordance with the comparison period is held. The count value held in the counter 152 is input as a digital signal to the data output unit 17 via the switch 153 that has been closed in accordance with the scanning from the column scanning unit 13 and the data transfer line 18.

The column scanning unit 13 is activated when, for example, a start pulse STR and a master clock MCK are supplied from the timing control unit 14 and drives a corresponding selection line SEL in synchronization with a drive clock CLK where the master clock MCK is set as a reference to read out latch data of the counter 152 (the held count value) to the data transfer line 18.

### SUMMARY

The common reference signal and the common auto zero signal AZ0 are input to each of the comparators 151 arranged in the row direction as described above. Therefore, in a case where an image of a subject that has no change in the row direction is picked up, for example, the pixel signals having a similar value are input to the large number of comparators 151, and as illustrated in FIG. 3, a width of the inversion timing dispersion (variation of the inverting timings) of the large number of comparators 151 is narrowed. That is, the outputs of the large number of comparators 151 are simultaneously inverted.

When the outputs of the large number of comparators 151 are simultaneously inverted as described above, noise is generated by IR-Drop, a current fluctuation, or the like, which may affect the other signal lines in some cases. Since a characteristic difference before and after the IR-Drop occurs is increased a count accuracy aggravation, an AD conversion error by interferences between the respective rows, or an image quality deterioration may occur in a subsequent stage of the comparator 151 too. The above-mentioned problem is more aggravated as the number of columns where the simultaneous inversion is carried out is increased. Therefore, as the number of pixels is increased, the influence is increased.

The present disclosure has been made in view of the above-mentioned circumstances, and it is desirable to suppress the noise generation caused by the simultaneous inversion of the comparator outputs.

According to an embodiment of the present disclosure, there is provided a comparator configured to compare a pixel signal from a pixel with a reference signal an offset level of which is changed in a stepwise manner and perform auto zero to set the pixel signal at the offset level of the reference signal in accordance with one of a plurality of auto zero signals having different timings for instructing the auto zero.

A plurality of the comparators can be arranged in a row direction corresponding to rows of the pixels arranged in a matrix, and the plurality of auto zero signals can be selectively received by the plural comparators arranged in the row direction.

The comparators arranged in the row direction can be divided into a plurality of groups each composed of predetermined number of the comparators, and the plurality of different auto zero signals can be sequentially input to each of the plurality of the groups each composed of the predetermined number of the comparators in a repeated manner.

The plurality of different auto zero signals can be sequentially input to each of the comparators arranged in the row direction in a repeated manner.

The comparators according to the embodiment of the present disclosure can include a dispersion unit configured to selectively output the plurality of different auto zero signals to the plurality of the comparators arranged in the row direction.

The plurality of auto zero signals can be set in a manner that the timings for instructing the auto zero are overlapped with one another.

The plurality of auto zero signals are set in a manner that the timings for instructing the auto zero are not overlapped with one another.

According to an embodiment of the present disclosure, there is provided a comparison method for a comparator configured to compare a pixel signal from a pixel with a reference signal an offset level of which is changed in a stepwise manner, the method including causing the comparator to perform auto zero to set the pixel signal at the offset level of the reference signal in accordance with one of a plurality of auto zero signals having different timings for instructing the auto zero.

According to another embodiment of the present disclosure, there is provided an AD converter including: a comparator configured to compare a pixel signal from a pixel with a reference signal an offset level of which is changed in a stepwise manner and perform auto zero to set the pixel signal at the offset level of the reference signal in accordance with one of a plurality of auto zero signals having different timings for instructing the auto zero; and a counter configured to perform counting at both edges of an input clock signal during a period until an output of the comparator is inverted and output an addition value or a subtraction value of a previous count value and a subsequent count value.

According to another embodiment of the present disclosure, there is provided a solid-state image pickup device including: a pixel unit composed of a plurality of pixels that are configured to output a pixel signal in accordance with incident light and arranged in a matrix; and an AD conversion unit including a comparator configured to compare the pixel signal from the pixel with a reference signal an offset level of which is changed in a stepwise manner and perform auto zero to set the pixel signal at the offset level of the reference signal in accordance with one of a plurality of auto zero signals having different timings for instructing the auto zero and a counter configured to perform counting at both edges of an input clock signal during a period until an output of the comparator is inverted and output an addition value or a subtraction value of a previous count value and a subsequent count value.

According to another embodiment of the present disclosure, there is provided an electronic apparatus including: an image pickup unit that uses a solid-state image pickup device including a pixel unit composed of a plurality of pixels that are configured to output a pixel signal in accordance with incident light and arranged in a matrix, and an AD conversion unit that includes a comparator configured to compare the pixel signal from the pixel with a reference signal an offset level of which is changed in a stepwise manner and perform auto zero to set the pixel signal at the offset level of the reference signal in accordance with one of a plurality of auto zero signals having different timings for instructing the auto zero and a counter configured to perform counting at both edges of an input clock signal during a period until an output of the comparator is inverted and output an addition value or a subtraction value of a previous count value and a subsequent count value.

According to the embodiments of the present disclosure, the pixel signal is subjected to the auto zero to be at the offset level of the reference signal in accordance with one of the plurality of auto zero signals having different timings for instructing the auto zero in the comparator.

According to the embodiments of the present disclosure, it is possible to suppress the noise generation caused by the simultaneous inversion of the comparator outputs.

### BRIEF DESCRIPTION OF THE DRAWINGS

FIG. 1 is a block diagram of a configuration example of a CIS in related art;

FIG. 2 is a circuit diagram of a configuration example of the comparator illustrated in FIG. 1;

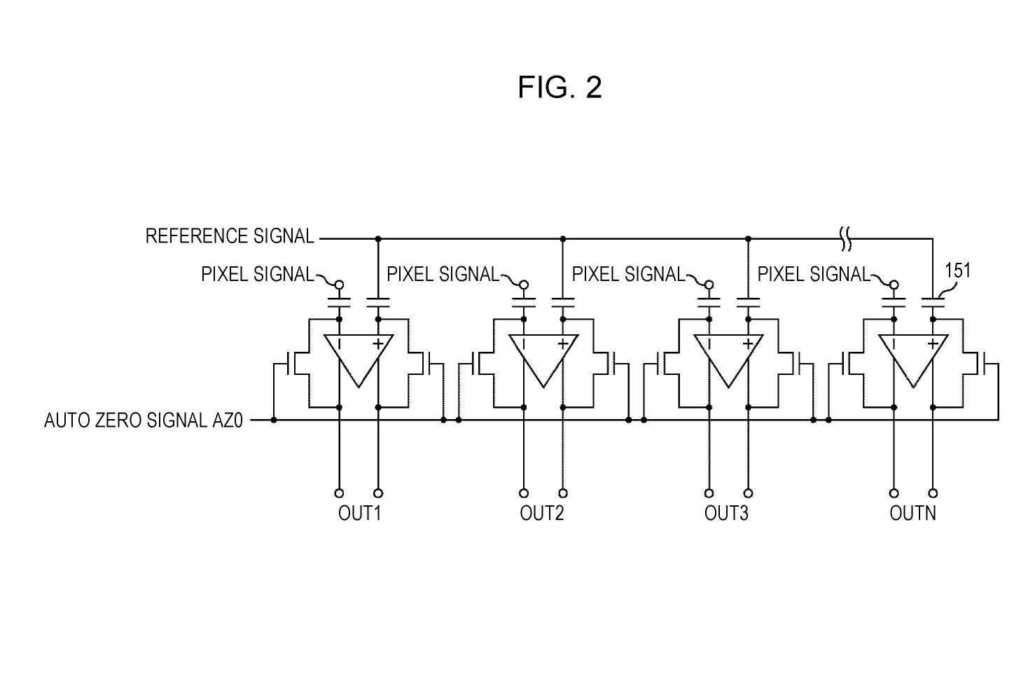

FIG. 3 illustrates an example of waveforms of an auto zero signal and a reference signal in the related art;

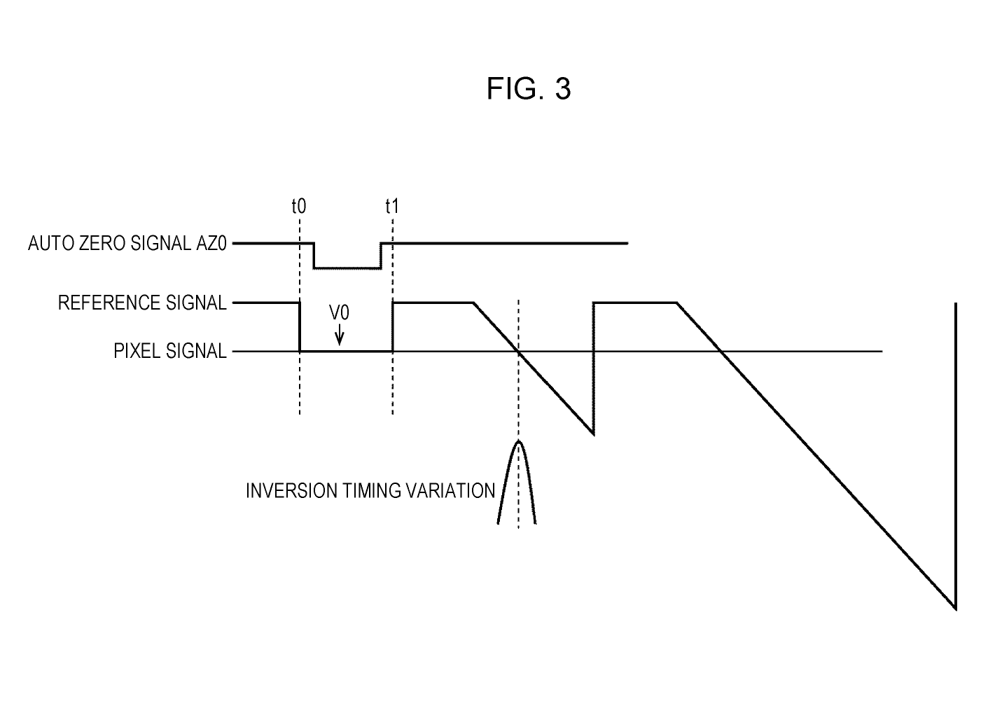

FIG. 4 is a block diagram of a configuration example of a CIS to which an embodiment of the present disclosure is applied;

FIG. 5 is a circuit diagram of a configuration example of the comparator illustrated in FIG. 4;

FIG. 6 illustrates a first example of waveforms of plural auto zero signals and a reference signal which are input to comparators arranged in a row direction;

FIG. 7 is an explanatory diagram for describing a case in which a voltage of the reference signal is not changed in a stepwise manner;

FIG. 8 illustrates a second example of the waveforms of the plural auto zero signals and the reference signal which are input to the comparators arranged in the row direction;

FIG. 9 illustrates a first example in which plural different auto zero signals are distributed to the comparators arranged in the row direction;

FIG. 10 illustrates a second example in which the plural different auto zero signals are distributed to the comparators arranged in the row direction; and

FIG. 11 illustrates a third example in which the plural different auto zero signals are distributed to the comparators arranged in the row direction.

### DETAILED DESCRIPTION OF EMBODIMENTS

Embodiments for carrying out the present disclosure (hereinafter, which will be referred to as embodiments) will be described in detail with reference to the drawings below. Configuration example of pixel

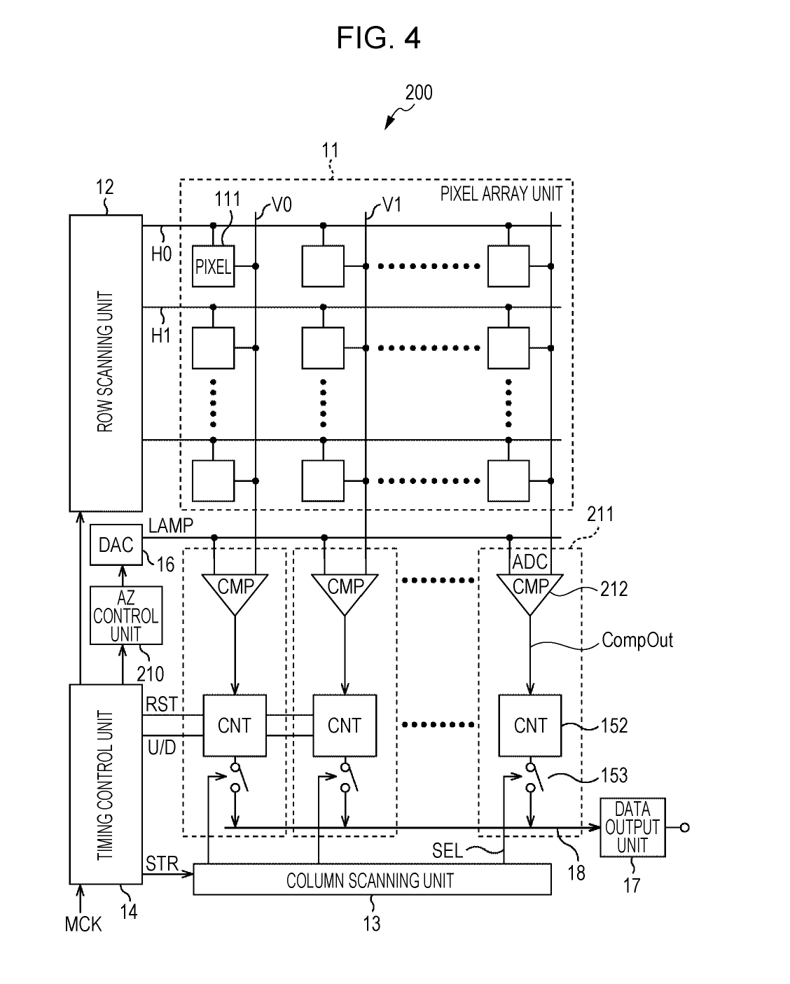

FIG. 4 illustrates a configuration example of a CIS 200 according to the present embodiment.

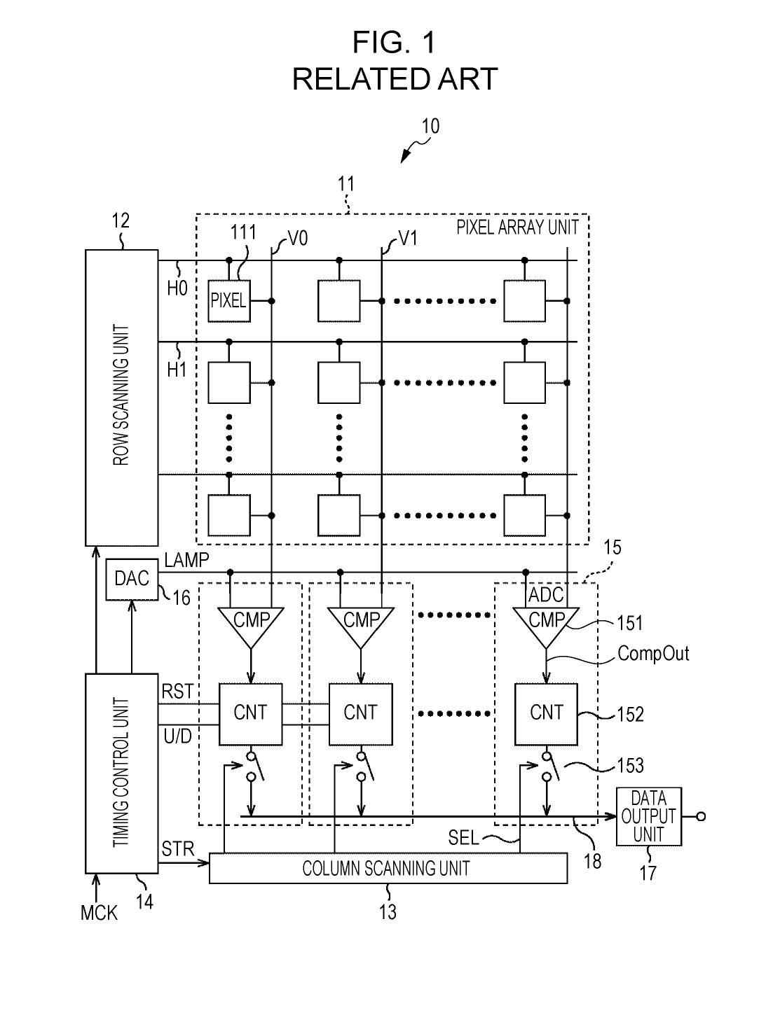

The CIS 200 is obtained by adding an auto zero (AZ) control unit 210 between the timing control unit 14 and the DAC 16 of the CIS 10 illustrated in FIG. 1 and replacing the comparator 151 of FIG. 1 with a comparator 212, so that the ADC 15 of FIG. 1 is accordingly replaced by with an ADC 211. The other components are same as those of the CIS 10 and assigned with the same reference symbols, and therefore a description thereof will be omitted.

The auto zero control unit 210 is configured to divide the auto zero signal AZ0 output from the timing control unit 14 into plural parts and also generate plural auto zero signals AZ1, AZ2, . . . by shifting timings at which the respective waveforms are set as low (that is, timings at which auto zero is carried out). The generated plural auto zero signals AZ1, AZ2, . . . are supplied to one of the plural comparators 212 arranged in the row direction via a signal line that is not illustrated in the drawing.

The auto zero control unit 210 also controls the DAC 16 to change an offset level of the reference signal generated by the DAC 16 during a period where the auto zero signals AZ1, AZ2, . . . are set as low to V1, V2, . . . in a stepwise manner by the same number of stages as the number of auto zero signals.

According to the present embodiment, three types of auto zero signals AZ1, AZ2, and AZ3 are generated on the basis of the auto zero signal AZ0. Therefore, the offset level of the reference signal is also changed in three stages of V1, V2, and V3.

It is however noted that the number of the auto zero signals AZ1, AZ2, . . . and the same number of stages of the offset level of the reference signal are not limited to three and may be changed in accordance with the number of pixel in the row direction, the influence from the simultaneous inversion of the outputs of the comparators 212, or the like.

The auto zero control unit 210 may also be built in the timing control unit 14 or the DAC 16.

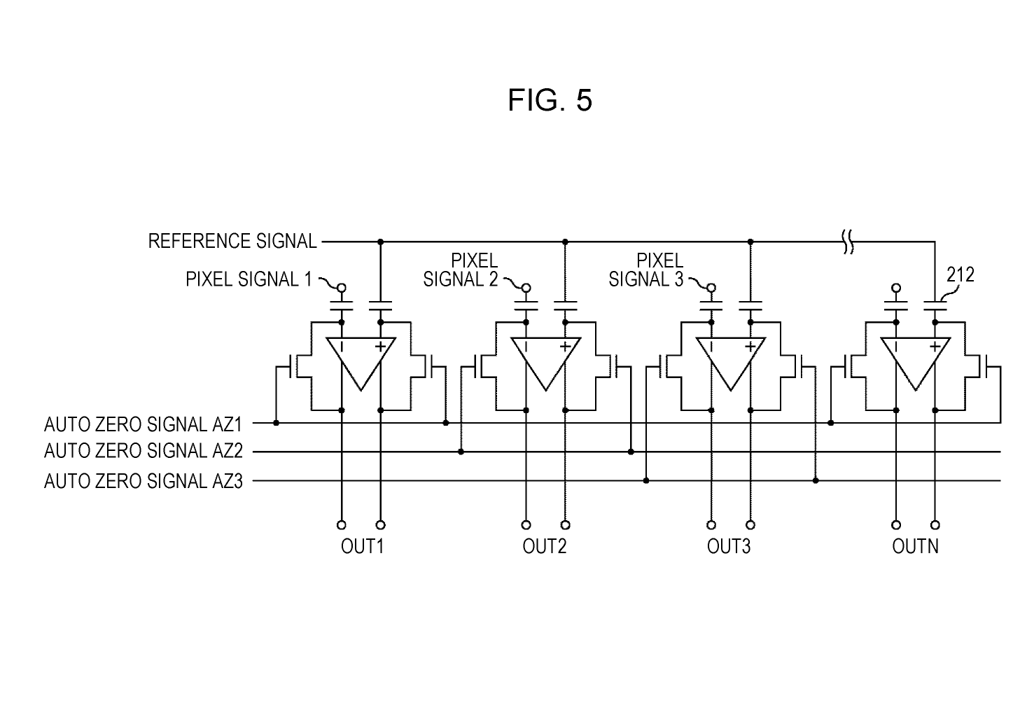

FIG. 5 illustrates a configuration example of the plural comparators 212 arranged in the row direction in the CIS 200 of FIG. 4.

As illustrated in FIG. 5, the pixel signals are input to the respective comparators 212 from the pixels 111 via the vertical signal lines Vn (n=0, 1, . . . , n+1). The common reference signal based on a control of the auto zero control unit 210 is also input to the respective comparators 212. Furthermore, one of the auto zero signals AZ1, AZ2, and AZ3 generated by the auto zero control unit 210 is input to each of the comparators 212.

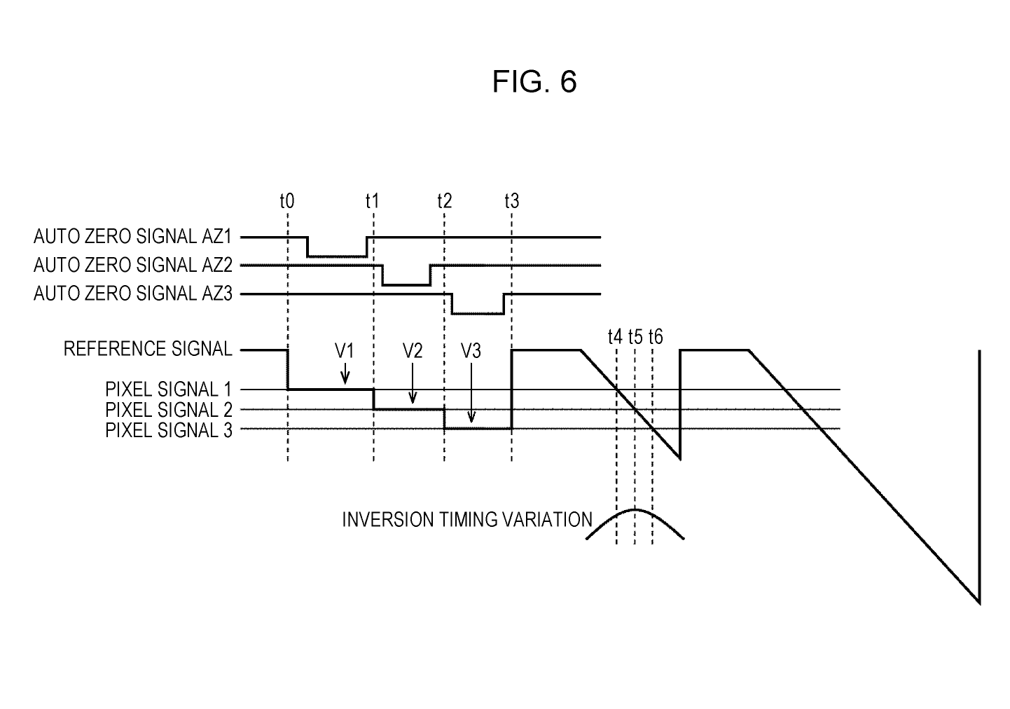

FIG. 6 illustrates a first example of waveforms of the auto zero signals AZ1, AZ2, and AZ3 and the reference signal that are input to the plural comparators 212 arranged in the row direction.

As illustrated in FIG. 6, the offset level of the reference signal is decreased in a stepwise manner to V1, V2, and V3, and the low timings for the auto zero signals AZ1, AZ2, and AZ3 are respectively shifted in tune with periods where the offset level of the reference signal is set at V1, V2, and V3. In this case, the comparator 212 supplied with the auto zero signal AZ1 is inverted at t4, the comparator 212 supplied with the auto zero signal AZ2 is inverted at t5, and the comparator 212 supplied with the auto zero signal AZ3 is inverted at t6. That is, the simultaneous inversion of the plural comparators 212 is suppressed, and the inverting timing can be dispersed.

As may be understood from FIG. 6 too, it is possible to widely disperse the inverting timings of the respective comparators 212 by increasing the number of types of the auto zero signals (that is, the number of stages of the reference signal).

The offset level of the reference signal is not limited to V1>V2>V3 as illustrated in FIG. 6, and for example, a similar effect can be obtained if mutually different values are used such as V1<V2<V3 or V2<V1<V3.

In a case where a voltage of the reference signal is not changed, the effect from the dispersion of the inverting timings of the respective comparators 212 is not obtained of course.

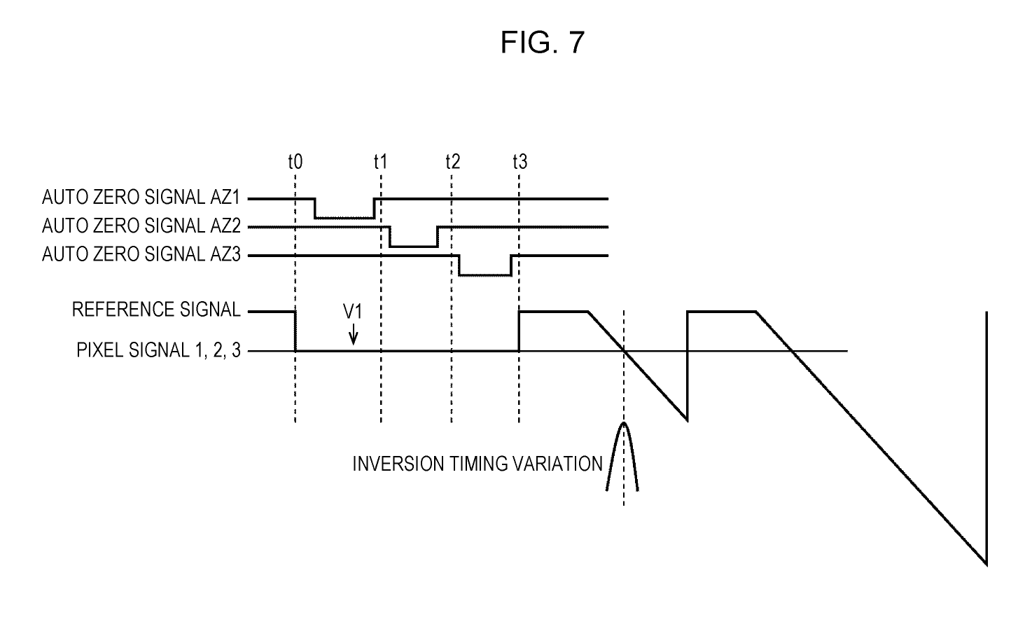

FIG. 7 illustrates a case in which the auto zero signals AZ1, AZ2, and AZ3 and the reference signal the offset level of which is constant are input to the plural comparators 212 arranged in the row direction. From FIG. 7 too, it may be apparent that the effect from the dispersion of the output inversions of the comparators 212 is not obtained unless the offset level of the reference signal is changed in a stepwise manner.

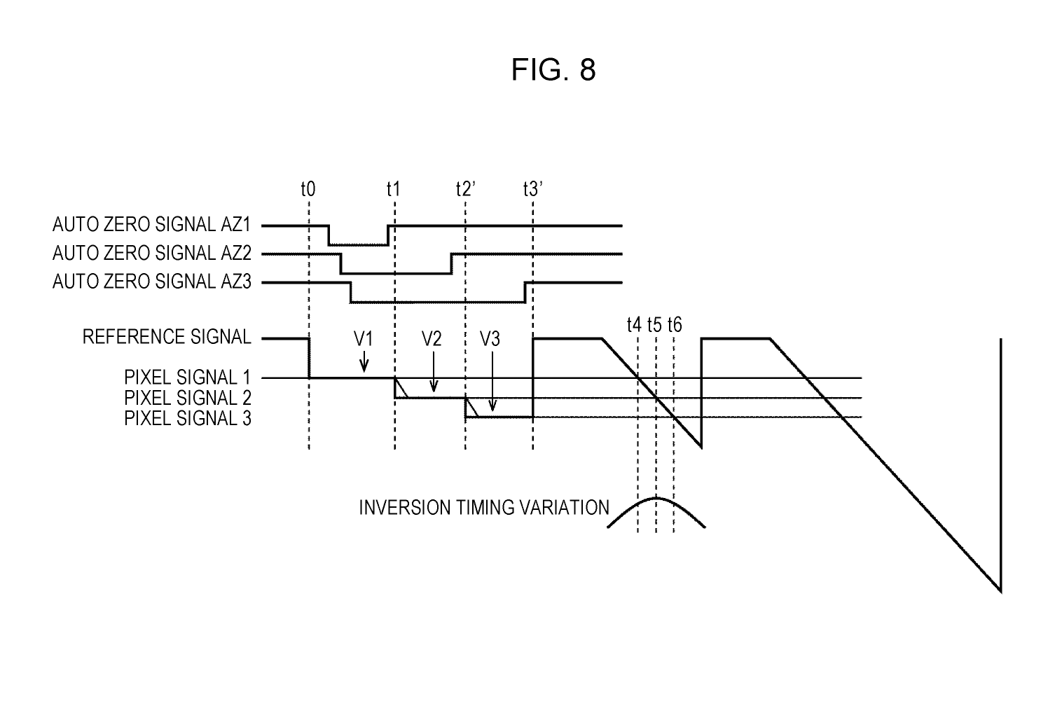

Next, FIG. 8 illustrates a second example of the waveforms of the auto zero signals AZ1, AZ2, and AZ3 and the reference signal which are input to the plural comparators 212 arranged in the row direction.

According to the second example illustrated in FIG. 8, the timings for setting the auto zero signals AZ2 and AZ3 as low are put ahead as compared with the first example illustrated in FIG. 6.

Specifically, the timing at which the auto zero signal AZ2 is set as low is put ahead of t1. With this setting, in the comparator 212 to which the auto zero signal AZ2 is input, the pixel signal is subjected to the auto zero to the offset level V1 of the reference signal at the timing when the auto zero signal AZ2 is set as low and is subsequently subjected to the auto zero to the offset level V2. At this time, if a voltage difference between V1 and V2 is set to be smaller than a voltage difference before and after the auto zero of the pixel signal by the auto zero signal AZ2 illustrated in FIG. 6, t2′ and t3′ can be brought forward, and it is therefore possible to shorten the auto zero period.

The same applies to the comparator 212 to which the auto zero signal AZ3 is input.

Starting timings for the auto zero signals AZ1, AZ2, and AZ3 may not be aligned with each other and may be set arbitrarily.

Next, a description will be given of an example in which the auto zero signals AZ1, AZ2, and AZ3 are distributed to the plural comparators 212 arranged in the row direction.

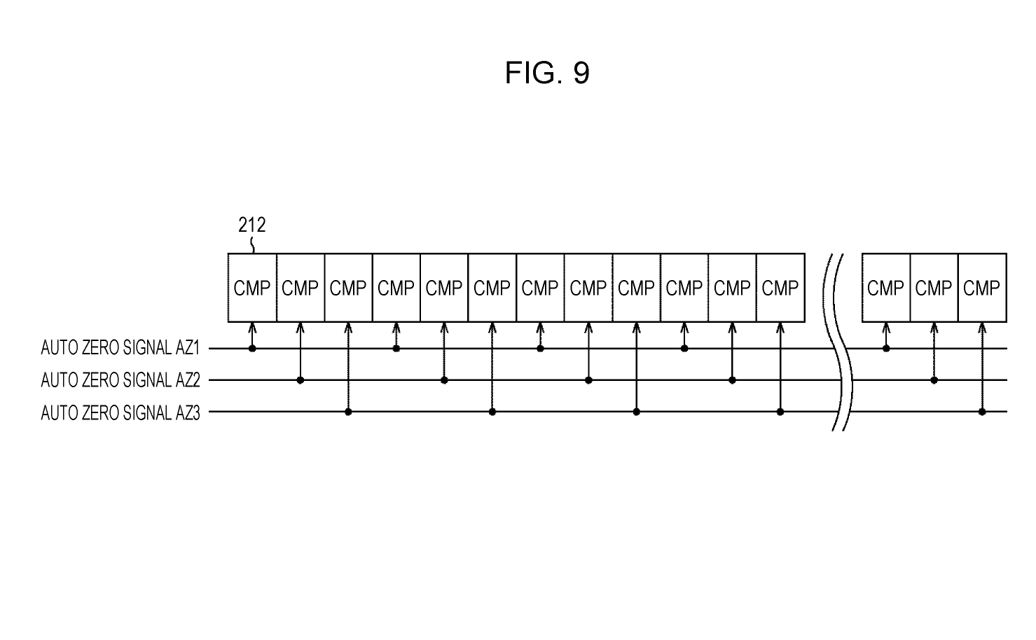

FIG. 9 illustrates an example in which the auto zero signals AZ1, AZ2, and AZ3 are sequentially supplied to the side-by-side comparators 212 so that the same auto zero signal as the auto zero signal to the adjacent comparator 212 is not supplied with respect to the plural comparators 212 arranged in the row direction.

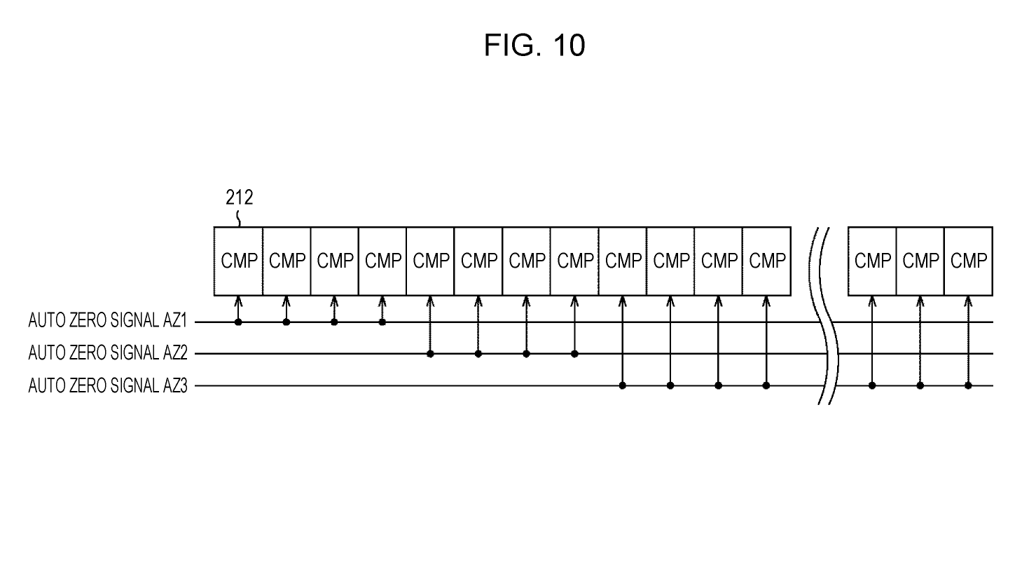

FIG. 10 illustrates an example in which the auto zero signals AZ1, AZ2, and AZ3 are sequentially supplied for every predetermined number of the plural comparators 212 arranged in the row direction (in the case of FIG. 10, every four comparators 212).

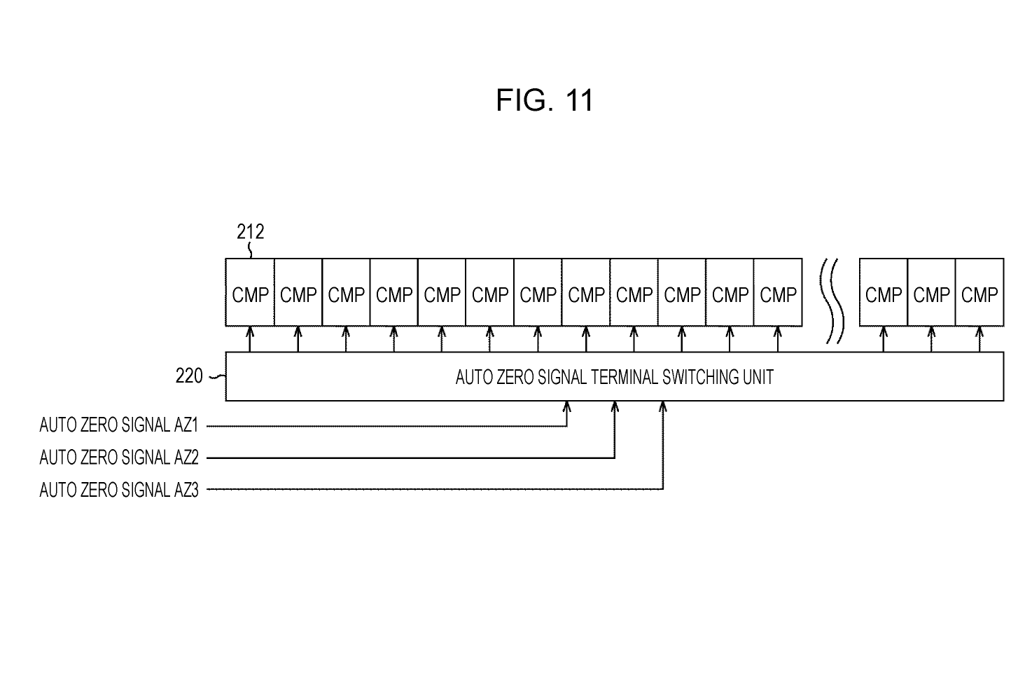

FIG. 11 illustrates an example in which an auto zero signal terminal switching unit 220 is provided in a front stage of the plural comparators 212 arranged in the row direction, and the auto zero signals AZ1, AZ2, and AZ3 are evenly distributed to the plural comparators 212 arranged in the row direction by the auto zero signal terminal switching unit 220.

A method of distributing the auto zero signals AZ1, AZ2, and AZ3 to the plural comparators 212 arranged in the row direction is not limited to the above-mentioned examples illustrated in FIG. 9 and FIG. 10. It is however noted that it is desirable to uniform the number of the comparators 212 to which the respective auto zero signals AZ1, AZ2, and AZ3 are supplied in any of the methods.

As described above, with the CIS 200 according to the embodiment of the present disclosure, the inverting timings of the outputs of the plural comparators 212 arranged in the row direction are dispersed, and it is possible to suppress the simultaneous inversion of the outputs of the plural comparators 212. Therefore, it is possible to avoid the adverse effect from the IR-Drop or the current fluctuation caused by the simultaneous inversion.

In addition, since the simultaneous inversion of the outputs of the plural comparators 212 can be suppressed, the embodiment of the present disclosure can contribute to the increase in the number of pixels of the CIS.

Furthermore, the CIS 200 according to the embodiment of the present disclosure can be applied to any electronic apparatus that has an image pickup function.

It should be understood by those skilled in the art that various modifications, combinations, sub-combinations and alterations may occur depending on design requirements and other factors insofar as they are within the scope of the appended claims or the equivalents thereof.

What is claimed is:

1. A comparator configured to compare a pixel signal from a pixel with a reference signal an offset level of which is changed in a stepwise manner, and
perform auto zero to set the pixel signal at the offset level of the reference signal in accordance with one of a plurality of auto zero signals having different timings for instructing the auto zero.

2. The comparator according to claim 1,
wherein the comparator is one of a plurality of comparators that are arranged in a row direction corresponding to rows of pixels arranged in a matrix, and
wherein the plurality of auto zero signals are selectively received by the plurality of the comparators arranged in the row direction.

3. The comparators according to claim 2,
wherein the comparators arranged in the row direction are divided into a plurality of groups each composed of predetermined number of the comparators, and
wherein the plurality of different auto zero signals are sequentially input to each of the plurality of the groups each composed of the predetermined number of the comparators in a repeated manner.

4. The comparators according to claim 2,
wherein the plurality of different auto zero signals are sequentially input to each of the comparators arranged in the row direction in a repeated manner.

5. The comparators according to claim 2, comprising:
a dispersion unit configured to selectively output the plurality of different auto zero signals to the plurality of the comparators arranged in the row direction.

6. The comparators according to claim 2,
wherein the plurality of auto zero signals are set in a manner that the timings for instructing the auto zero are overlapped with one another.

7. The comparators according to claim 2,
wherein the plurality of auto zero signals are set in a manner that the timings for instructing the auto zero are not overlapped with one another.

8. A comparison method for a comparator configured to compare a pixel signal from a pixel with a reference signal an offset level of which is changed in a stepwise manner, the method comprising:
causing the comparator to perform auto zero to set the pixel signal at the offset level of the reference signal in accordance with one of a plurality of auto zero signals having different timings for instructing the auto zero.

9. An AD converter comprising:
a comparator configured to compare a pixel signal from a pixel with a reference signal an offset level of which is changed in a stepwise manner and perform auto zero to set the pixel signal at the offset level of the reference signal in accordance with one of a plurality of auto zero signals having different timings for instructing the auto zero; and
a counter configured to perform counting at both edges of an input clock signal during a period until an output of the comparator is inverted and output an addition value or a subtraction value of a previous count value and a subsequent count value.

10. A solid-state image pickup device comprising:
a pixel unit composed of a plurality of pixels that are configured to output a pixel signal in accordance with incident light and arranged in a matrix; and
an AD conversion unit including
a comparator configured to compare the pixel signal from the pixel with a reference signal an offset level of which is changed in a stepwise manner and perform auto zero to set the pixel signal at the offset level of the reference signal in accordance with one of a plurality of auto zero signals having different timings for instructing the auto zero, and
a counter configured to perform counting at both edges of an input clock signal during a period until an output of the comparator is inverted and output an addition value or a subtraction value of a previous count value and a subsequent count value.

11. An electronic apparatus comprising:
an image pickup unit that uses a solid-state image pickup device including
a pixel unit composed of a plurality of pixels that are configured to output a pixel signal in accordance with incident light and arranged in a matrix, and
an AD conversion unit including
a comparator configured to compare the pixel signal from the pixel with a reference signal an offset level of which is changed in a stepwise manner and perform auto zero to set the pixel signal at the offset level of the reference signal in accordance with one of a plurality of auto zero signals having different timings for instructing the auto zero, and
a counter configured to perform counting at both edges of an input clock signal during a period until an output of the comparator is inverted and output an addition value or a subtraction value of a previous count value and a subsequent count value.
